(19) United States
(12) Patent Application Publication
(10) Pub. No.: US 2021/0225945 A1
(43) Pub. Date: Jul. 22, 2021

(54) OLED TOUCH COMPONENT AND OLED DISPLAY DEVICE WITH THE SAME

(71) Applicant: BOE TECHNOLOGY GROUP CO., LTD., Beijing (CN)

(72) Inventors: Changfeng LI, Beijing (CN); Haisheng WANG, Beijing (CN); Yingming LIU, Beijing (CN); Xiaoliang DING, Beijing (CN); Rui XU, Beijing (CN)

(21) Appl. No.: 16/303,184

(22) PCT Filed: May 18, 2018
(86) PCT No.: PCT/CN2018/087537

§ 371 Date: Nov. 20, 2018

(30) Foreign Application Priority Data
May 22, 2017 (CN) 201710362493.7

(51) Int. Cl. H01L 27/32; G06F 3/041

(52) U.S. Cl. CPC H01L 27/323; G06F 3/0412

(57) ABSTRACT

The present disclosure provides an OLED touch component and an OLED display device with the same. the OLED touch component includes an array substrate formed with a wire bonding region; a film package disposed on the array substrate, and having a first slope which is provided at a side of the film package with respect to a wire bonding region; an insulating layer disposed on the film package and the array substrate, wherein a portion of the insulating layer covering the first slope is formed with a second slope; and a touch electrode disposed at the insulating layer and connected with a plurality of touch electrode leads, wherein a portion of the touch electrode lead located at the second slope is formed with a bending structure.

### CROSS REFERENCE

This application is a National-Stage filing of International Application No. PCT/CN2018/087537, filed on May 18, 2018, which is based upon and claims priority to Chinese Patent Application No. 201710362493.7, filed on May 22, 2017, the entire contents thereof are incorporated herein by reference.

### TECHNICAL FIELD

The present disclosure relates to touch screen technique field, and in particular, to an OLED touch component and an OLED display device with the same.

### BACKGROUND

The Manufacture of touch electrodes on OLED display devices to realize touch functions is increasing in popularity. Referring to FIG. 1, a related OLED touch component is shown, which mainly includes an array substrate 101, a film package 102, and an insulating layer 103 which are sequentially laminated. Wherein touch electrodes 104 are formed on the film package 102 (TFE film), and then when the touch electrode leads 105 are transferred to the array substrate 101 through the film package 102 for hot pressing. The gap between the film package 102 and the array substrate 101 is large due to the film package 102 with a thickness about ten micrometers, therefore, when crossing such a large gap, the touch electrode lead 105 is liable to be broken.

### SUMMARY

According to one embodiment of the present disclosure, an OLED touch component is provided, which includes: an array substrate formed with a wire bonding region; a film package disposed on the array substrate, and having a first slope which is provided at a side of the film package with respect to a wire bonding region; an insulating layer disposed on the film package and the array substrate, wherein a portion of the insulating layer covering the first slope is formed with a second slope; and a touch electrode disposed at the insulating layer and connected with a plurality of touch electrode leads, wherein a portion of the touch electrode lead located at the second slope is formed with a bending structure.

According to another embodiment of the present disclosure, an OLED display device is provided, wherein the OLED display device comprises the OLED touch component.

### BRIEF DESCRIPTION OF THE DRAWINGS

FIG. 1 is a schematic view of a related art OLED touch component;

FIG. 2 is a schematic view of an OLED touch component according to an exemplary embodiment;

FIG. 3 is a partial enlarged view of a bending structure of a touch electrode lead of the OLED touch component shown in FIG. 2.

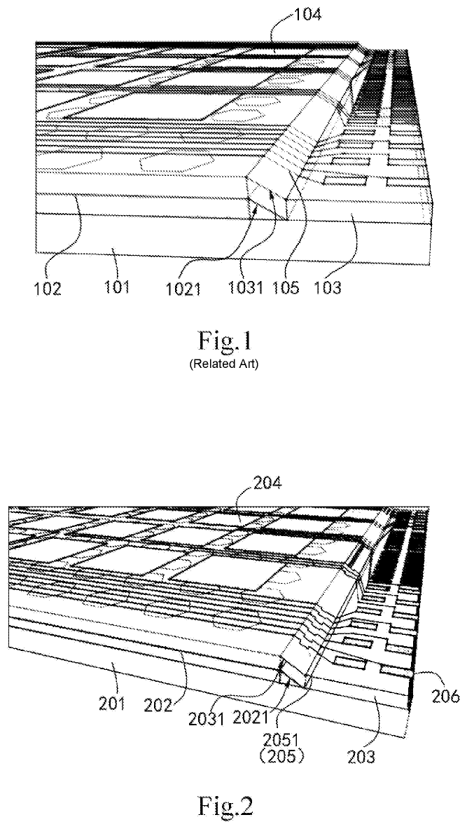

### DETAILED DESCRIPTION

The same reference numerals in the drawings denote the same or similar structures, and thus their detailed description will be omitted. Example embodiments will now be described more fully with reference to the accompanying drawings. However, the example embodiments can be embodied in a variety of forms, and should not be construed as being limited to the embodiment set forth herein; to the contrary, these embodiments are provided so that this disclosure will be thorough and complete, the concept of the example embodiments is fully conveyed to those skilled in the art.

An Embodiment of an OLED Touch Component

Referring to FIG. 2, FIG. 2 representatively illustrates a schematic diagram of an OLED touch assembly that can embody the principles of the present disclosure. It will be readily understood by those skilled in the art that in order to use the OLED touch component proposed by the present disclosure for other types of touch devices, various modifications, additions, substitutions, deletions, or other modifications are made to the specific embodiments described below, these variations are still within the scope of the principles of the OLED touch component proposed by the present disclosure.

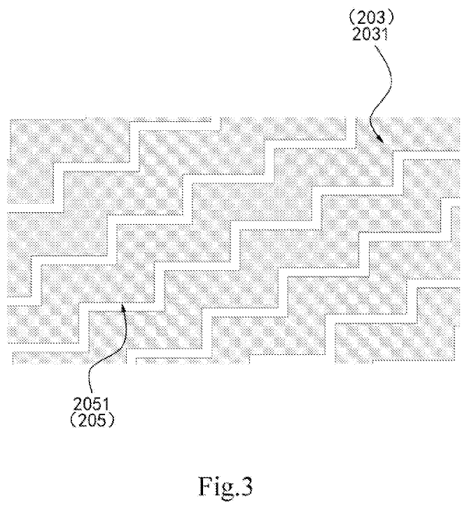

As shown in FIG. 2, in the embodiment, the OLED touch component provided by the present disclosure mainly includes an array substrate 201, a film package 202 (TFE film), an insulating layer 203, a plurality of touch electrodes 204 and a plurality of touch electrode leads 205. Referring to FIG. 3, it representatively shows a partial enlarged view of a bending structure 2051 of the touch electrode lead 205. The main structures of the OLED touch component provided by the present disclosure will be described in detail below in conjunction with the above drawings.

As shown in FIG. 2, in the embodiment, the array substrate 201, the film package 202 and the insulating layer 203 are sequentially stacked, that is, the film package 202 is disposed on the array substrate 201, the insulating layer 203 may preferably be a silicon nitride layer (SiOyNx), which is disposed on the film package 202 and the array substrate 201. Wherein the film package 202 has a first slope 2021 which is provided at a side of the film package 202 with respect to a wire bonding region 206 (also called a binding zone), and the wire bonding region 206 is usually disposed on a side edge of the array substrate 201. Correspondingly, a portion of the insulating layer 203 covering the first slope 2021 is formed with a second slope 2031.

As shown in FIG. 2, in the embodiment, a plurality of touch electrodes 204 (metal) are disposed on the insulating layer 203 and connected with a plurality of touch electrode leads 205, the touch electrode lead 205 is transferred to the array substrate 201 through the film package 202 and connected to the wire bonding region 206. Wherein the routing path of the touch electrode lead 205 passes through the second slope 2031, and its portion positioned at the second slope 2031 is formed with a bending structure 2051. Through the design of the above-mentioned bending structure 2051 of the touch electrode lead 205, the present disclosure can alleviate the stress concentration phenomenon occurred at the touch electrode lead 205, so as to improve the ductility of the touch electrode lead 205 and thereby reducing the problem of disconnection caused by the break of the touch electrode lead 205.

Preferably, as shown in FIG. 2, in the present embodiment, the bending direction of the bending structure 2051 of the touch electrode lead 205 is preferably parallel to the slope surface of the second slope 2031.

Preferably, as shown in FIG. 2, in the present embodiment, the OLED touch component of the present disclosure includes a plurality of touch electrodes 204 and a plurality of touch electrode leads 205, wherein the bending direction of bending structures 2051 of the plurality of touch electrode leads 205 is identical (for example, parallel to the slope surface of the second slope 2031), the bending structures 2051 of the plurality of touch electrode leads 205 are formed at the same position, and the bending structures 2051 of the plurality of touch electrode leads 205 have the same shape. It should be noted that, in other embodiments, the bending direction, formation position and shape of the bending structure 2051 of each touch electrode lead 205 are not limited to the same design of the three, for example, at least one of the above three may be the same, or different, and the like, and are not limited thereto.

Further, as shown in FIG. 2, in the present embodiment, the bending structure 2051 of the touch electrode lead 205 may preferably be saw-tooth shape and formed with at least one tooth. Wherein the tooth shape of the bending structure 2051 is rectangular, trapezoidal or triangular, and it is not limited to the shape shown in FIG. 2.

Furthermore, the bending structure 2051 of the touch electrode lead 205 may further preferably be in a step shape and have a plurality of steps, such as the bending structure 2051 shown in FIG. 3. Preferably, the number, direction and size of steps the plurality of touch electrode leads 205 are identical, but are not limited thereto, for example, it is also possible for a design whereat least one of the number, the direction and the size of steps of each of the touch electrode leads 205 are identical, or designed to be different therefrom each other. It should be noted that, in the practical applications, the bending structure 2051 is designed to be in a step shape, so as to further disperse the stress applied at a portion of the touch electrode lead 205 corresponding to the second slope 2031, thusly further alleviating the stress concentration phenomenon, further improving the ductility and thereby further reducing the problem of disconnection caused by the break of the touch electrode lead 205.

In addition, in other embodiments, the bending structure of the touch electrode lead may also be selected from an arc shape or irregular shape, and is not limited to the saw-tooth shape or the step shape in the present embodiment.

It should be noted herein that the OLED touch component illustrated in the figures and described in this specification is only one example of many of the OLED touch components that can employ the principles of the present disclosure. It should be clearly understood that the principles of the present disclosure are in no way limited to any detail of the OLED touch component shown in the figures or described in this specification or any part of the OLED touch component.

In summary, the present disclosure provides an OLED touch component, wherein the portion of the touch electrode lead 205 corresponding to the second slope 2031 of the insulating layer 203 is designed to be bent, so as to effectively alleviate the stress concentration phenomenon occurred at the portion of the touch electrode lead 205, improve the ductility of the touch electrode lead 205, thereby reducing the problem of disconnection caused by the break of the touch electrode leads 205.

An Embodiment of an OLED Display Device

The present disclosure also provides an OLED display device. The main difference between the OLED display device and the existing device is that the OLED display device of the present disclosure includes the OLED touch component provided by the present disclosure. Accordingly, compared with the existing device, the OLED display device provided by the present disclosure could significantly reduce problem of disconnection caused by the break of the touch electrode lead, thereby improving the product yield of the OLED display device and having higher economic value.

The present disclosure has been described with reference to a few exemplary embodiments, and it is understood that the terms used are illustrative and exemplary and not restrictive. Since the present disclosure can be embodied in various forms without departing from the spirit or substance of the invention, it should be understood that the above embodiments are not limited to any of the foregoing details, but should be construed broadly within the spirit and scope defined by the appended claims, all changes and modifications that fall into the scope of the claims and their equivalents should be covered by the accompanying claims.

1. An OLED touch component comprising,
an array substrate formed with a wire bonding region;
a film package disposed on the array substrate and having a first slope which is provided at a side of the film package with respect to a wire bonding region;
an insulating layer disposed on the film package and the array substrate, wherein a portion of the insulating layer covering the first slope is formed with a second slope; and
a touch electrode disposed at the insulating layer and connected with a plurality of touch electrode leads, wherein
a portion of the plurality of touch electrode leads located at the second slope is formed with a bending structure.

2. The OLED touch component according to the claim 1, characterized in that:
a bending direction of the bending structure of the touch electrode lead is parallel to a slope surface of the second slope.

3. The OLED touch component according to the claim 1, characterized in that:
the bending structures of the plurality of touch electrode leads have the same bending direction.

4. The OLED touch component according to the claim 1, characterized in that:
the bending structures of the plurality of touch electrode leads are formed at the same position.

5. The OLED touch component according to the claim 1, characterized in that:
the bending structures of the plurality of touch electrode leads have the same shape.

6. The OLED touch component according to the claim 1, characterized in that:
the bending structure is in a step shape and has a plurality of steps.

7. The OLED touch component according to the claim 6, characterized in that:
a number of steps of the plurality of touch electrode leads is the same.

8. The OLED touch component according to the claim 6, characterized in that:
the plurality of the touch electrode leads have the same step direction.

9. The OLED touch component according to the claim 6, characterized in that:
the plurality of touch electrode leads have the same step size.

10. The OLED touch component according to the claim 1, characterized in that:
the bending structure is in a saw-tooth shape and formed with at least one tooth.

11. (canceled)

12. The OLED touch component according to the claim 10, characterized in that:
a shape of the tooth of the bending structure is rectangular, trapezoidal or triangular.

13. The OLED touch component according to the claim 1, characterized in that:
the bending structure is in an arc shape or an irregular shape.

14. An OLED display device, characterized in that:
the OLED display device comprises an OLED touch component which comprises:
an array substrate formed with a wire bonding region;
a film package disposed on the array substrate, and having a first slope which is provided at a side of the film package with respect to a wire bonding region;
an insulating layer disposed on the film package and the array substrate, wherein a portion of the insulating layer covering the first slope is formed with a second slope; and
a touch electrode disposed at the insulating layer and connected with a plurality of touch electrode leads, wherein a portion of the plurality of touch electrode leads located at the second slope is formed with a bending structure.

15. The OLED display device according to the claim 14, characterized in that:
a bending direction of the bending structure of the touch electrode lead is parallel to a slope surface of the second slope.

16. The OLED display device according to the claim 14, characterized in that:
the bending structures of the plurality of touch electrode leads have the same bending direction.

17. The OLED display device according to the claim 14, characterized in that:
the bending structures of the plurality of touch electrode leads are formed at the same position.

18. The OLED display device according to the claim 14, characterized in that:
the bending structure is in a step shape and has a plurality of steps.

19. The OLED display device according to the claim 14, characterized in that:
the bending structure is in a saw-tooth shape and formed with at least one tooth.
